(19) United States
(12) Patent Application Publication
(10) Pub. No.: US 2021/0400845 A1
(43) Pub. Date: Dec. 23, 2021

(54) STORAGE DEVICE

(71) Applicant: Kioxia Corporation, Tokyo (JP)

(72) Inventor: Koji UENO, Toda Saitama (JP)

(73) Assignee: Kioxia Corporation, Tokyo (JP)

(21) Appl. No.: 17/173,473

(22) Filed: Feb. 11, 2021

(30) Foreign Application Priority Data
Jun. 22, 2020 (JP) 2020-106719

(51) Int. Cl. H05K 7/20

(52) U.S. Cl. CPC H05K 7/20336

(57) ABSTRACT

According to one embodiment, a storage device includes: a substrate having a first surface; at least one semiconductor device, which includes a storage unit, disposed on the first surface; a first component that includes a base end portion connected to the first surface, and an intermediate portion connected to the base end portion and separated from the first surface; and a second component connected to the first component and separated from the first surface. The second component is electrically coupled to the semiconductor device through the first component and a wiring.

### CROSS-REFERENCE TO RELATED APPLICATION(S)

This application is based upon and claims the benefit of priority from Japanese Patent Application No. 2020-106719, filed Jun. 22, 2020, the entire contents of which are incorporated herein by reference.

### FIELD

Embodiments described herein relate generally to a storage device including a storage unit.

### BACKGROUND

As a storage device including a storage unit, a Solid State Drive (SSD) or the like in which a semiconductor memory is mounted on a substrate is used. Heat generated by a controller, the semiconductor memory, or the like mounted on the substrate is dissipated by using, for example, a heat pipe.

### DESCRIPTION OF THE DRAWINGS

FIG. 1 is a schematic plan view showing a configuration of a storage device according to a first embodiment.

FIG. 2 is a schematic side view showing a configuration of the storage device according to the first embodiment.

FIG. 3 is a block diagram of the storage device according to the first embodiment.

FIG. 4 is a cross-sectional view showing a structure of a heat pipe of the storage device according to the first embodiment.

FIG. 5 is a schematic view showing a connection between the heat pipe and a PLP capacitor of the storage device according to the first embodiment.

FIG. 6 is a schematic view showing a connection between the heat pipe and a substrate of the storage device according to the first embodiment.

FIG. 7 is a schematic plan view showing a configuration of a storage device according to a modification of the first embodiment.

FIG. 8 is a schematic side view showing a configuration of the storage device according to the modification of the first embodiment.

FIG. 9 is a schematic view showing a connection between a heat pipe and a PLP capacitor of the storage device according to the modification of the first embodiment.

FIG. 10 is a schematic plan view showing a configuration of a storage device according to a second embodiment.

FIG. 11 is a schematic view showing a connection between a heat pipe and a PLP capacitor of the storage device according to the second embodiment.

FIG. 12 is a schematic view showing a connection between the heat pipe and a substrate of the storage device according to the second embodiment.

FIG. 13 is a schematic side view showing a configuration of a storage device according to a third embodiment.

FIG. 14 is a schematic side view showing a configuration of a storage device according to another embodiment.

### DETAILED DESCRIPTION

Embodiments provide a storage device in which components are efficiently mounted on a mounting surface of a substrate of the storage device.

In general, according to one embodiment, the storage device includes a substrate having a first surface; at least one semiconductor device, which includes a storage unit, disposed on the first surface; a first component that includes a base end portion connected to the first surface, and an intermediate portion connected to the base end portion and separated from the first surface; and a second component connected to the first component and separated from the first surface. The second component is electrically coupled to the semiconductor device through the first component and a wiring.

Hereinafter, embodiments will be described with reference to the drawings. In description of the drawings, the same components are denoted by the same reference numerals, and description thereof is omitted.

### (First Embodiment)

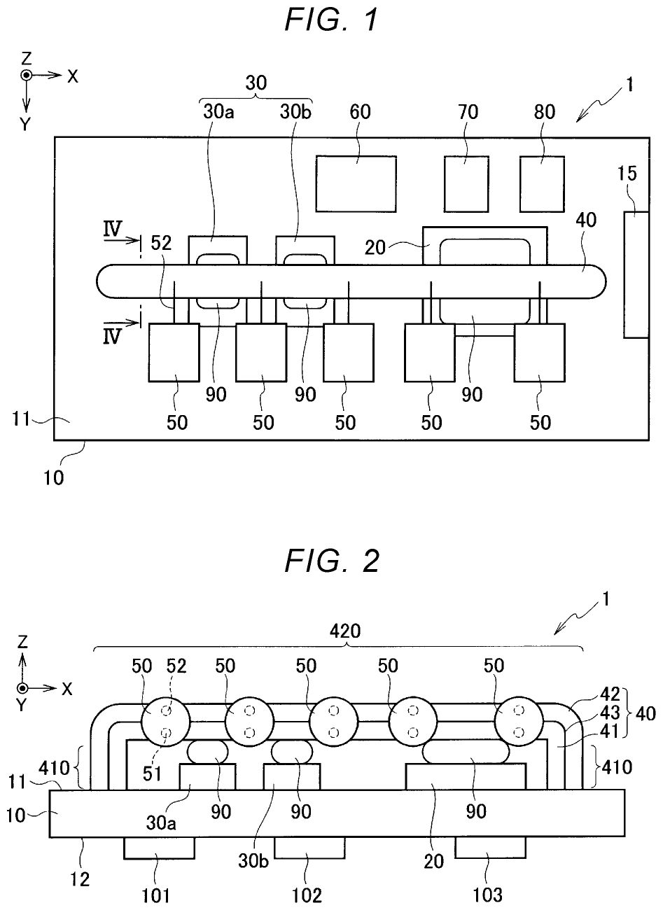

A storage device 1 according to a first embodiment shown in FIG. 1 is, for example, an SSD. The storage device 1 includes a substrate 10 and a plurality of semiconductor devices including a first storage unit 30a and a second storage unit 30b which are disposed on a first surface 11 of the substrate 10. Further, the storage device 1 further includes a heat pipe 40, which is a first component disposed on the first surface 11, and PLP capacitors 50 mounted on the heat pipe 40.

In FIG. 1, a plane normal direction of the first surface 11 of the substrate 10 is a Z-axis direction, and a plane perpendicular to the Z-axis direction is an XY plane (the same applies hereinafter). Further, a left-right direction of a paper surface in FIG. 1 is an X-axis direction, and an up-down direction of the paper surface is a Y-axis direction.

Hereinafter, the storage units including the first storage unit 30a and the second storage unit 30b and mounted on the substrate 10 are also collectively referred to as a “storage unit 30”. Hereinafter, the storage unit 30 may be implemented as a non-volatile semiconductor memory. The storage unit 30 includes, for example, a NAND flash memory.

As shown in FIG. 2, the substrate 10 includes the first surface 11 and a second surface 12 which are opposite to each other. A semiconductor device or a second component can be mounted on both the first surface 11 and the second surface 12. Hereinafter, the first surface 11 and the second surface 12 are collectively referred to as a “mounting surface”. A wiring electrically connecting the semiconductor device and the second component disposed on the mounting surface is disposed on the substrate 10. The wiring disposed on the substrate 10 is also referred to as a “wiring pattern” below. A printed circuit board (PCB) or the like may be used for the substrate 10.

The semiconductor device disposed on the mounting surface of the substrate 10 is also referred to as a “mounting device” below. The storage device 1 includes one or more such mounting devices, a controller 20, the storage unit 30, a Dynamic Random Access Memory (DRAM) 60, a power supply control circuit 70, and a PLP circuit 80 which are mounted on the first surface 11.

Further, the storage device 1 includes one or more such mounting devices, and peripheral ICs 101 to 103 mounted on the second surface 12. The peripheral ICs 101 to 103 are, for example, a reset IC that resets a state of the storage device 1, a temperature sensor that monitors a temperature of the storage device 1, a crystal oscillator that supplies a frequency that is a reference for an operating clock of the storage device 1, or the like.

Any mounting device may be mounted on either the first surface 11 or the second surface 12. For example, although the peripheral ICs 101 to 103 are mounted on the second surface 12 in the above discussion, the peripheral ICs 101 to 103 may be mounted on the first surface 11, while remaining within the scope of the present disclosure.

The controller 20 may be implemented by a circuit such as a System-on-a-Chip (SoC). The controller 20 comprehensively controls an operation of the storage device 1. Each function of the controller 20 may be implemented by the controller 20 executing a firmware. Each function of the controller 20 may be implemented by dedicated hardware in the controller 20.

The controller 20 controls communication between a host device (not shown) that can be connected to the storage device 1 and the storage device 1. The host device is connected to the storage device 1 via a card edge connector 15 disposed at an end portion of the substrate 10.

For example, the controller 20 receives a command from the host device and controls the storage unit 30 so as to execute a write operation or a read operation. Alternatively, the controller 20 controls the storage unit 30 to execute an erasing operation for erasing stored data.

The DRAM 60 is used for storing management information of the storage unit 30 and for caching data. For example, the controller 20 uses the DRAM 60 to temporarily store data transmitted from the host device and stored in the storage unit 30. Further, the controller 20 uses the DRAM 60 to temporarily store data read from the storage unit 30 and transmitted to the host device.

During start-up or upon receipt of a read command or a write command from the host device, a part or all of the management information stored in the storage unit 30 is loaded (cached) into the DRAM 60. The controller 20 updates the management information loaded into the DRAM 60 and backs up the management information in the storage unit 30 at a predetermined timing. The management information includes, for example, mapping data indicating a correspondence between a logical address specified by the host device and a physical address of the storage unit 30.

The power supply control circuit 70 controls on/off of power supplied to the mounting devices of the storage device 1. The power supply control circuit 70 supplies power to the controller 20, the storage unit 30, the DRAM 60, or the like, or stops supplying the power, according to the operation of the storage device 1.

The PLP circuit 80 is a mounting device for power loss protection that protects the storage device 1 when the power supplied to the storage device 1 from the outside of the storage device 1 is lost. Details of the PLP circuit 80 will be described later.

As shown in FIG. 2, the heat pipe 40 includes base end portions 410 connected to the first surface 11 and an intermediate portion 420 that is connected to the base end portion 410 and is separated from the first surface 11 so as to be located above the first surface 11. The heat pipe 40 has a pipe shape, and both ends of the heat pipe 40 are the base end portions 410 connected to the first surface 11.

The heat pipe 40 is thermally connected to at least a part of the mounting devices arranged on the first surface 11 of the substrate 10. In the storage device 1, the controller 20 and the storage unit 30 are thermally connected to the intermediate portion 420 of the heat pipe 40 via heat conductive sheets 90. Heat generated in the controller 20 and the storage unit 30 is dissipated by propagating the heat through the heat pipe 40 and transmitting the heat. A material having high thermal conductivity is used for the heat conductive sheet 90. For example, a sheet made of a silicone-based resin or the like may be used for the heat conductive sheet 90.

A case where the mounting devices thermally connected to the heat pipe 40 are the controller 20 and the storage unit 30 has been described, but the mounting devices thermally connected to the heat pipe 40 are not limited to the controller 20 and the storage unit 30.

The PLP capacitors 50 are connected to the heat pipe 40 and separated from (e.g., above) the first surface 11. The PLP circuit controls charging and discharging of the PLP capacitors 50.

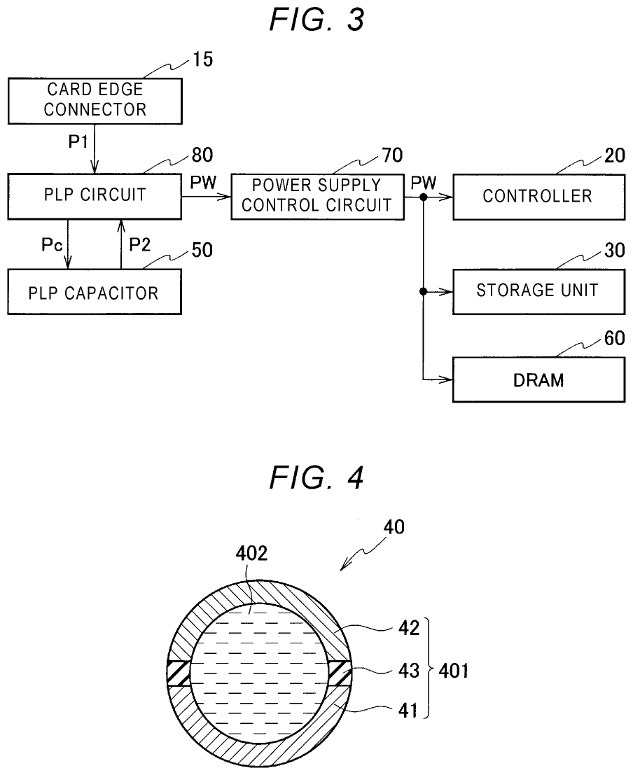

FIG. 3 is a block diagram showing a path through which the power is supplied to the mounting devices of the storage device 1. Operations of the PLP circuit 80 and the power supply control circuit 70 will be described below with reference to FIG. 3.

The PLP circuit 80 monitors power P1 supplied from the card edge connector 15 to the storage device 1. When the power P1 is within a predetermined range, the PLP circuit 80 supplies the power P1 supplied from the card edge connector 15 to the power supply control circuit 70 as power PW to be supplied to the mounting devices.

When detecting an unexpected power loss of the storage device 1 based on a decrease in the power P1, the PLP circuit 80 notifies the controller 20 of the power loss. When being notified of the power loss, the controller 20 controls the PLP circuit 80 to switch the power PW supplied to the power supply control circuit 70 from the power P1 supplied from the card edge connector 15 to the power P2 supplied by the PLP capacitors 50.

The PLP capacitors 50 supply the power to the storage device 1 when power supply from the outside of the storage device 1 is lost. For example, while the power P1 is supplied to the storage device 1 from the card edge connector 15, the PLP circuit 80 supplies power Pc to the PLP capacitors 50 to charge the PLP capacitors 50. The PLP capacitors 50 are charged with electric charges corresponding to the power for operating the storage device 1 for a certain period of time. For the PLP capacitor 50, for example, a polymer tantalum capacitor or aluminum electrolytic capacitor having a capacitance value of about 10 μF to 100 μF, or the like may be used.

As described above, when the power P1 supplied from the card edge connector 15 decreases, the electric charges discharged by the PLP capacitors 50 is supplied to the mounting devices of the storage device 1. The controller 20 prepares for power cutoff set at a time of normal shutdown during a period in which the storage device 1 is operated by the electric charges supplied by the PLP capacitors 50. For example, under control of the controller 20, contents of a cache buffer stored in the DRAM 60 are written to or erased from the storage unit 30, and a mapping table is updated or backed up in the storage unit 30.

As described above, the storage device 1 including the PLP capacitors 50 executes a predetermined operation for the power cutoff even at a time of an unintended shutdown due to the power loss. As a result, data stored in the storage unit 30 is protected. Although a case where the storage device 1 includes five PLP capacitors 50 has been described as an example, the number of the PLP capacitors 50 in the storage device 1 can be set optionally.

As shown in FIG. 4, the heat pipe 40 has a structure in which a working fluid 402 is filled inside a cylindrical pipe 401. FIG. 4 is a cross-sectional view taken along an IV-IV direction of FIG. 1. The pipe 401 includes a first conductive portion 41 and a second conductive portion 42 that are electrically insulated from each other. Specifically, the first conductive portion 41 and the second conductive portion 42 are electrically insulated by an insulating portion 43 disposed in a band shape between the first conductive portion 41 and the second conductive portion 42. The insulating portion 43 extends from one end portion of the pipe 401 to the other end portion along an extending direction of the pipe 401.

As described above, the heat pipe 40 is formed of two conductive parts, the first conductive portion 41 and the second conductive portion 42. The first conductive portion 41 and the second conductive portion 42 are parallel to each other from the base end portion 410 to the intermediate portion 420 of the heat pipe 40.

In the storage device 1, the first conductive portion 41 of the heat pipe 40 faces the first surface 11 of the substrate 10, and apart of the first conductive portion 41 is in contact with the heat conductive sheets 90.

The material having high thermal conductivity is used for the first conductive portion 41 and the second conductive portion 42. For example, a metal material such as copper (Cu) maybe used for the first conductive portion 41 and the second conductive portion 42. For the insulating portion 43, for example, a ceramic material or a resin may be used.

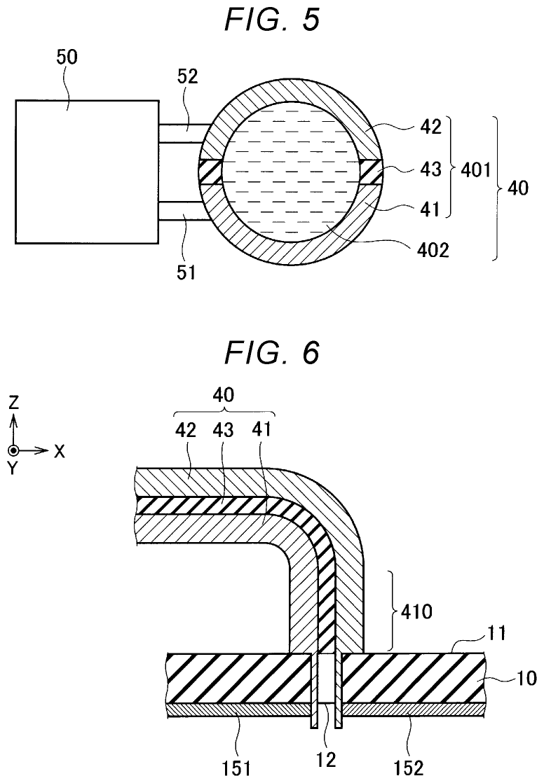

The PLP capacitor 50 is a lead type capacitor, and as shown in FIG. 5, a lead of a first electrode 51 of the PLP capacitor 50 is connected to the first conductive portion 41 of the heat pipe 40. A lead of a second electrode 52 of the PLP capacitor 50 is connected to the second conductive portion 42 of the heat pipe 40. For example, the first electrode 51 and the first conductive portion 41 or the second electrode 52 and the second conductive portion 42 may be connected by soldering.

The base end portion 410 of the heat pipe 40 is electrically connected to the wiring disposed on the substrate 10. FIG. 6 shows an example in which the base end portion 410 of the heat pipe 40 is connected to the wiring disposed on the second surface 12 of the substrate 10. In an example shown in FIG. 6, columnar-shaped tips of the base end portions 410 of the first conductive portion 41 and the second conductive portion 42 of the heat pipe 40 penetrate through via holes reaching the second surface 12 of the substrate 10 from the first surface 11. For example, the heat pipe 40 maybe mounted on the substrate 10 by press-fitting the tips of the base end portions 410 of the first conductive portion 41 and the second conductive portion 42 into the through via holes formed on the first surface 11.

As shown in FIG. 6, the tip of the base end portion 410 of the first conductive portion 41 of the heat pipe 40 is electrically connected to a power supply wiring pattern 151. The power supply wiring pattern 151 is connected to the PLP circuit 80 that charges the PLP capacitors 50. As described above, the first electrode 51 of the PLP capacitor 50 is connected to the PLP circuit 80 via the first conductive portion 41 of the heat pipe 40 and the power supply wiring pattern 151. The tip of the base end portion 410 of the first conductive portion 41 and the power supply wiring pattern 151 may be connected by, for example, soldering.

The tip of the base end portion 410 of the second conductive portion 42 of the heat pipe 40 is electrically connected to a GND wiring pattern 152. The second electrode 52 of the PLP capacitor 50 is connected to the GND of the storage device 1 via the second conductive portion 42 of the heat pipe 40 and the GND wiring pattern 152. The tip of the base end portion 410 of the second conductive portion 42 and the GND wiring pattern 152 maybe connected by, for example, soldering.

Although FIG. 6 shows an example in which the wiring pattern is disposed on the second surface 12 of the substrate 10, the wiring pattern may be disposed on the first surface 11 of the substrate 10 or inside the substrate 10. Further, the first conductive portion 41 of the heat pipe 40 may be electrically connected to the GND wiring pattern 152, and the second conductive portion 42 of the heat pipe 40 may be electrically connected to the power supply wiring pattern 151.

During the power loss of the storage device 1, the PLP capacitor 50 supplies the electric charges to the mounting devices mounted on the substrate 10 via the heat pipe 40 and the wiring disposed on the substrate 10. As described above, in the storage device 1, the heat pipe 40, which generally does not have a structure in which a power supply wiring or the GND is provided, is used as a power path for charging and discharging the PLP capacitors 50.

As described above, in the storage device 1, the PLP capacitors 50 are mounted on the heat pipe 40, and the PLP capacitors 50 are disposed at a position separated from the first surface 11 of the substrate 10. According to the storage device 1 in which the PLP capacitors 50 are disposed above the first surface 11, it is not necessary to secure a region for connection of the PLP capacitors 50 on the first surface 11 of the substrate 10.

Generally, when the storage device is small in size, an area of the mounting surface of the substrate on which the components constituting the storage device are mounted is narrow. Therefore, as a size of the storage device is reduced, it becomes difficult to mount the components on the substrate.

On the other hand, in the storage device 1, a large-sized electronic component such as the PLP capacitor 50 is not directly disposed on the first surface 11 of the substrate 10. Therefore, a region of the first surface 11 on which the mounting devices other than the components mounted on the heat pipe 40 are disposed can be widened. Therefore, according to the storage device 1, a degree of freedom in layout design when the mounting devices are mounted on the mounting surface of the substrate 10 can be increased.

Further, in the storage device 1, for example, as shown in FIG. 1, in a plan view seen from the plane normal direction (the Z-axis direction) of the first surface 11, the mounting devices can be disposed on the first surface 11 of the substrate 10 such that at least a part of the PLP capacitors 50 overlaps the mounting devices.

As described above, in the storage device 1, by using a space above the first surface 11 of the substrate 10 as a region in which the components are disposed, the components forming the storage device 1 can be efficiently mounted on the first surface 11 of the substrate 10.

In rework work such as repair of the storage device 1, reflow heating is performed for a replacement of components, or the like. For example, in order to detach a component from the substrate 10, the reflow heating is performed to melt the entire substrate 10 or a soldered portion of a component to be replaced. Alternatively, reflow heating for soldering the component to the substrate 10 is performed. At this time, it is necessary to protect the PLP capacitors 50 from damage caused by the reflow heating. Therefore, it is necessary to detach the PLP capacitors 50 from the substrate 10 before the reflow heating.

In this case, in the storage device 1, the PLP capacitors 50 can be protected from the damage caused by the reflow heating simply by detaching the heat pipe 40 from the substrate 10. Therefore, workability of the rework work can be improved in the storage device 1 as compared with a case where the plurality of PLP capacitors 50 are directly soldered to the first surface 11 of the substrate 10.

Further, a step of mounting the PLP capacitors 50 on the heat pipe 40 and a step of mounting the mounting devices or the like on the substrate 10 can be performed independently. For example, the heat pipe 40 on which the PLP capacitors 50 are mounted may be prepared in advance, and the heat pipe 40 may be attached on the substrate 10 on which the mounting devices are mounted. By increasing efficiency of a manufacturing step of the storage device 1 in this way, a manufacturing cost of the storage device 1 can be reduced.

As described above, in the storage device 1 according to the first embodiment, the PLP capacitors 50 are mounted on the heat pipe 40 and are not directly disposed on the first surface 11. Therefore, according to the storage device 1, the components forming the storage device 1 can be efficiently disposed in a space of a form factor limited by a small area of the mounting surface of the substrate 10.

The case where the PLP capacitors 50 are mounted on the heat pipe 40 has been described above, but capacitors other than the PLP capacitors 50 may be mounted on the heat pipe 40. For example, a bypass capacitor or the like mounted on the substrate 10 as a countermeasure against power supply noise maybe mounted on the heat pipe 40. Alternatively, the second component other than the capacitor may be mounted on the heat pipe 40. By providing the second component above the first surface 11, an area of a region on the first surface 11 on which the components are mounted can be substantially increased.

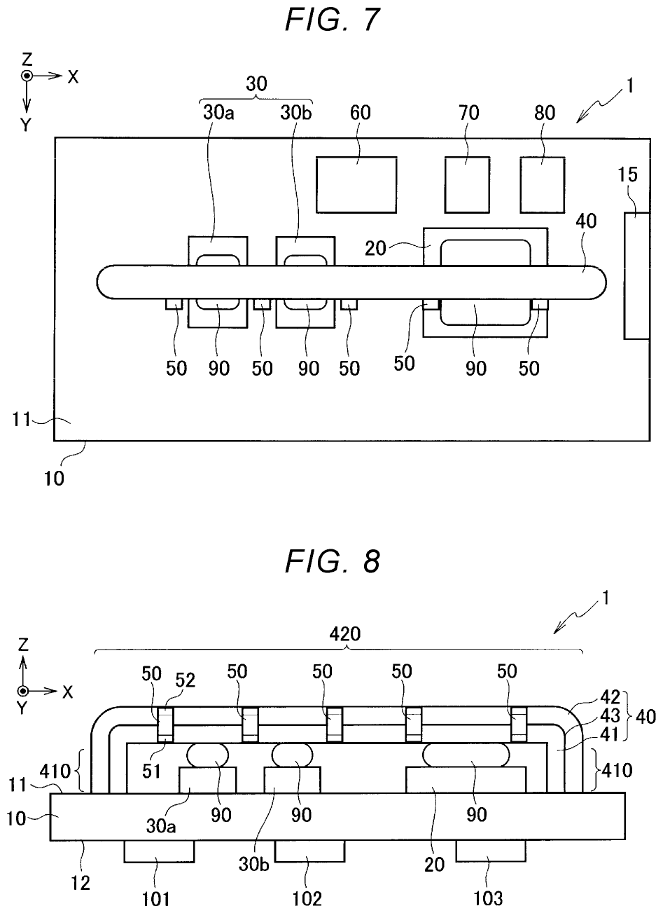

The PLP capacitors 50 may be chip capacitors. FIGS. 7 and 8 show an example in which the PLP capacitors 50 of chip capacitors are mounted on the heat pipe 40.

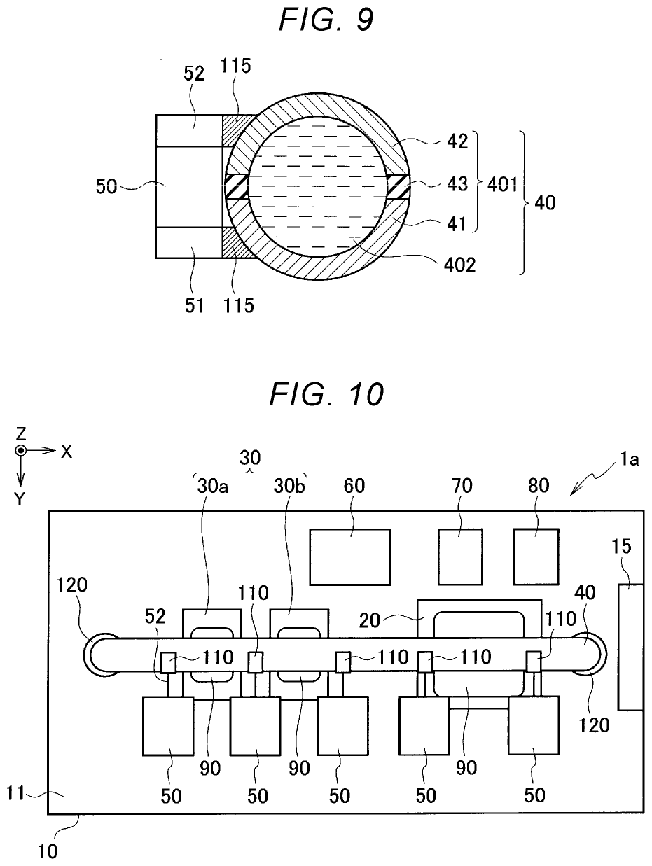

As shown in FIG. 9, the first electrode 51, which is one end portion of the PLP capacitor 50, which is a chip capacitor, is electrically connected to the first conductive portion 41, and the second electrode 52, which is the other end portion of the PLP capacitor 50, is electrically connected to the second conductive portion 42. The electrodes of the PLP capacitor 50 and the heat pipe 40 may be electrically connected by, for example, a solder 115.

### (Second Embodiment)

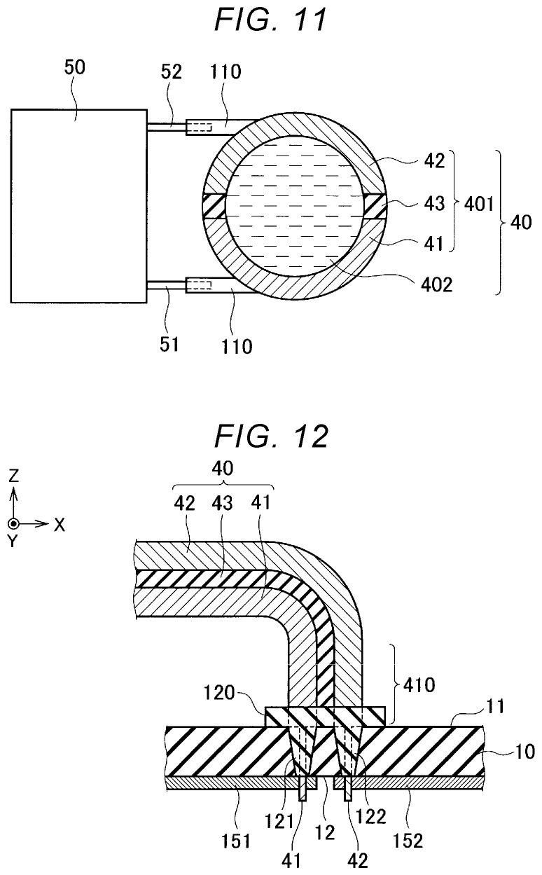

In a storage device 1a according to a second embodiment shown in FIG. 10, the PLP capacitors 50 and the heat pipe 40 are electrically connected via component connectors 110. The component connectors 110 are disposed in the intermediate portion 420 of the heat pipe 40. For example, as shown in FIG. 11, the first electrode 51 and the second electrode 52 of the PLP capacitor 50 are inserted into the component connectors 110. The first electrode 51 of the PLP capacitor 50 is electrically connected to the first conductive portion 41 of the heat pipe 40 via the component connector 110. The second electrode 52 of the PLP capacitor 50 is electrically connected to the second conductive portion 42 of the heat pipe 40 via the component connector 110.

The PLP capacitor 50 is detachably connected to the component connectors 110. Therefore, in the storage device 1a, as compared with a case where the PLP capacitors 50 are soldered to the heat pipe 40, work of mounting the PLP capacitors 50 onto the heat pipe 40 and work of detaching the PLP capacitors 50 from the heat pipe 40 can be made efficient.

Further, in the storage device 1a, the heat pipe 40 and the wiring pattern of the substrate 10 are electrically connected via a mounting connector 120. The mounting connector 120 is an embedded socket embedded in the substrate 10 as shown in FIG. 12, for example. A first socket 121 and a second socket 122 of the mounting connector 120 are press-fitted into, for example, the through via holes penetrating from the first surface 11 to the second surface 12 of the substrate 10.

The tip of the base end portion 410 of the first conductive portion 41 of the heat pipe 40 is inserted into the first socket 121 of the mounting connector 120 shown in FIG. 12. The tip of the base end portion 410 of the first conductive portion 41 penetrates the first socket 121 of the mounting connector 120 and is exposed to the second surface 12 of the substrate 10. Then, the base end portion 410 of the first conductive portion 41 is electrically connected to the power supply wiring pattern 151 disposed on the second surface 12 of the substrate 10.

The tip of the base end portion 410 of the second conductive portion 42 of the heat pipe 40 is inserted into the second socket 122 of the mounting connector 120. The tip of the base end portion 410 of the second conductive portion 42 penetrates the second socket 122 of the mounting connector 120 and is exposed to the second surface 12 of the substrate 10. Then, the base end portion 410 of the second conductive portion 42 is electrically connected to the GND wiring pattern 152 disposed on the second surface 12 of the substrate 10.

The heat pipe 40 is detachably connected to the mounting connector 120. Therefore, in the storage device 1a, it is easy to mount the heat pipe 40 on the substrate 10 and detach the heat pipe 40 from the substrate 10.

Therefore, according to the storage device 1a, it is easy to detach the heat pipe 40 from the substrate 10 with the PLP capacitors 50 mounted on the heat pipe 40, for example, in order to protect the PLP capacitors 50 from the damage caused by the reflow heating in the rework work. Further, according to the storage device 1a, the workability when the heat pipe 40 on which the PLP capacitors 50 are mounted is remounted on the substrate 10 is improved.

The storage device 1a according to the second embodiment is substantially the same as the storage device 1 according to the first embodiment in other configurations, and duplicate description will be omitted.

### (Third Embodiment)

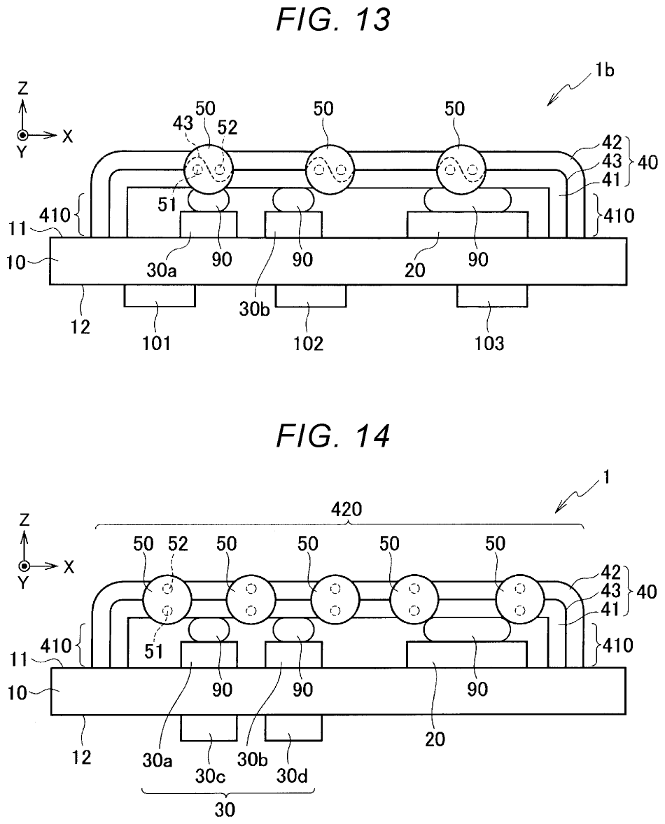

In a storage device 1b according to a third embodiment, as shown in FIG. 13, the first electrodes 51 and the second electrodes 52 of the PLP capacitors 50 are arranged along a direction (the X-axis direction) parallel to the first surface 11. Therefore, the insulating portion 43 of the heat pipe 40 includes a portion formed in a curved shape so as to bypass a connection portion between the first electrode 51 and the first conductive portion 41 and a connection portion between the second electrode 52 and the second conductive portion 42. That is, a configuration of the heat pipe 40 is different between the storage device 1 according to the first embodiment in which the insulating portion 43 is a linear shape and the storage device 1b.

In the storage device 1 shown in FIG. 1, when the PLP capacitors 50 are mounted at a contact portion between the heat pipe 40 and the heat conductive sheets 90, leads which are the electrodes of the PLP capacitors 50 are sandwiched between the heat pipe 40 and the heat conductive sheets 90. In that configuration, a contact area between the heat conductive sheets 90 and the heat pipe 40 is reduced, and efficiency of heat conduction from the mounting devices to the heat pipe 40 is reduced.

On the other hand, in the storage device 1b shown in FIG. 13, the leads which are the electrodes of the PLP capacitors 50 are not sandwiched between the heat pipe 40 and the heat conductive sheets 90. Therefore, according to the storage device 1b, it is possible to reduce a decrease in the efficiency of the heat conduction from the mounting devices to the heat pipe 40.

### (Other Embodiments)

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

Although an example in which the first component on which the PLP capacitors 50 are mounted is the heat pipe 40 has been described above, the first component on which the second component such as the PLP capacitors 50 are mounted above the first surface 11 is not limited to the heat pipe 40. That is, the PLP capacitors 50 may be mounted on the first component other than the heat pipe 40, which includes a portion separated from the first surface 11 so as to be located above the first surface 11.

For example, the PLP capacitors 50 may be mounted on a portion of a bus bar mounted on the first surface 11 away from the first surface 11 so as to be located above the first surface 11. The bus bar is a conductive bar attached to an upper part of the substrate 10 for a purpose of strengthening a power supply terminal, a GND terminal, or the like.

Further, the heat pipe 40 shown above is formed of two conductive parts, the first conductive portion 41 and the second conductive portion 42, but two heat pipes each including one conductive portion may be used. That is, the storage device 1 may include a first heat pipe that is electrically connected to the first electrodes 51 of the PLP capacitors 50 and a second heat pipe that is electrically connected to the second electrodes 52 of the PLP capacitors 50. The first heat pipe is electrically connected to the power supply wiring pattern 151, and the second heat pipe is electrically connected to the GND wiring pattern 152. The first heat pipe and the second heat pipe are electrically insulated. For example, an insulator may be disposed between the first heat pipe and the second heat pipe.

Further, although an example in which the storage units 30 are disposed on the first surface 11 of the substrate 10 has been described above, the storage units 30 may be disposed on both the first surface 11 and the second surface 12. For example, as shown in FIG. 14, the controller 20, the first storage unit 30a, and the second storage unit 30b may be disposed on the first surface 11, and a third storage unit 30c and a fourth storage unit 30d may be disposed on the second surface 12. Although FIG. 14 shows an example in which the heat pipe 40 is not disposed on the second surface 12, the heat pipe 40 may be disposed on the second surface 12, or the PLP capacitors 50 may be mounted on the heat pipe 40 disposed on the second surface 12.

What is claimed is:

1. A storage device, comprising:
a substrate having a first surface;
at least one semiconductor device, which includes a storage unit, disposed on the first surface;
a first component that includes a base end portion connected to the first surface, and an intermediate portion connected to the base end portion and separated from the first surface; and
a second component connected to the first component and separated from the first surface, wherein the second component is electrically coupled to the semiconductor device through the first component and a wiring.

2. The storage device according to claim 1, wherein
at least a portion of the second component overlaps the semiconductor device when viewed from a top of the first surface.

3. The storage device according to claim 1, wherein
the first component includes a heat pipe that is thermally coupled to the semiconductor device and configured to dissipate heat generated by the semiconductor device to an outside of the semiconductor device.

4. The storage device according to claim 3, wherein
the heat pipe includes a first conductive portion and a second conductive portion that are electrically insulated from each other and parallel to each other.

5. The storage device according to claim 4, wherein
the second component includes a capacitor having a first electrode connected to the first conductive portion and a second electrode connected to the second conductive portion.

6. The storage device according to claim 5, wherein
the heat pipe includes an insulating portion disposed between the first conductive portion and the second conductive portion, and
wherein the insulating portion has a shape that bypasses a connection portion between the first electrode and the first conductive portion and a connection portion between the second electrode and the second conductive portion.

7. The storage device according to claim 5, wherein
the capacitor is configured to supply electric charge to the semiconductor device during power loss.

8. The storage device according to claim 1, wherein
the storage unit includes a non-volatile semiconductor memory, and
the semiconductor devices include a controller that controls the non-volatile semiconductor memory.

9. The storage device according to claim 1, further comprising a connector coupling
the second component to the first component, wherein the second component is detachably connected to the connector.

10. The storage device according to claim 1, further comprising a connector coupling
the first component to the wiring, wherein the first component is detachably connected to the connector.

11. The storage device according to claim 1, wherein the wiring is disposed on a second surface of the substrate opposite to the first surface.

12. A storage device, comprising:
a substrate having a first surface and a second surface opposite to the first surface;
at least one semiconductor device including a storage unit disposed on the first surface;
a wiring disposed on the second surface of the substrate;
a heat pipe, disposed over the semiconductor device, including a first portion separated from the first surface; and
at least one capacitor coupled to the heat pipe, wherein the at least one capacitor is electrically coupled to the semiconductor device through the heat pipe and the wiring.

13. The storage device of claim 12, wherein the capacitor is configured to supply electric charges to the semiconductor device during power loss.

14. The storage device of claim 12, wherein the heat pipe includes a first conductive portion and a second conductive portion that are electrically insulated from each other.

15. The storage device of claim 14, wherein the heat pipe further includes an insulating portion disposed between the first conductive portion and the second conductive portion.

16. The storage device of claim 1, wherein the heat pipe is thermally coupled to the semiconductor device and the storage unit via a plurality of heat conductive sheets, respectively.
